(19) United States
(12) Patent Application Publication
(10) Pub. No.: US 2023/0130557 A1
(43) Pub. Date: Apr. 27, 2023

(54) REACTANT GAS PULSE DELIVERY

(71) Applicant: Lam Research Corporation, Fremont, CA (US)

(72) Inventors: Krishna BIRRU, Fremont, CA (US); Leonard Wai Fung KHO, San Francisco, CA (US); Anand CHANDRASHEKAR, Fremont, CA (US); Michael BOWES, Scotts Valley, CA (US); Yong SUN, Fremont, CA (US); Xing ZHANG, San Jose, CA (US); Sumit Subhash SINGH, Bengaluru (IN)

(21) Appl. No.: 17/907,959

(22) PCT Filed: Mar. 3, 2021
(86) PCT No.: PCT/US2021/020748

§ 371 Date: Aug. 29, 2022

(30) Foreign Application Priority Data
Mar. 4, 2020 (IN) 202031009211

(51) Int. Cl. C23C 16/455; C23C 16/04; C23C 16/52; H01L 21/02; H01L 21/285; H01L 21/768

(52) U.S. Cl. CPC C23C 16/45544; C23C 16/045; C23C 16/52; H01L 21/0228; H01L 21/28562; H01L 21/76816

(57) ABSTRACT

Providing herein are methods of delivery of gas reactants to a processing chamber and related apparatus.

### INCORPORATED BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

A challenge in semiconductor processing is achieving process uniformity across as large an expanse of a processed wafer as possible.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect of the disclosure relates to method involving performing an inhibition treatment on a substrate. The method involves introducing co-flow pulses of a reactive inhibition gas and a metal precursor gas to a chamber, wherein each co-flow pulse comprises a pulse of the reactive inhibition gas and a pulse of the metal precursor gas, wherein the pulse of the reactive inhibition gas and the pulse of the metal precursor gas are offset and overlap in time. The pulses (also referred to as doses) are measured from when the gas is flowed from its gas source. The inhibition treatment inhibits metal nucleation.

In some embodiments, the pulse of the metal precursor gas and the pulse of the reactive inhibition gas end or start at the same time.

In some embodiments, each pulse of the reactive inhibition gas is separated from subsequent pulses of the reactive inhibition gas by a purge and each pulse of the metal precursor gas is separated from subsequent pulses of the metal precursor gas by a purge.

In some embodiments, the metal is one of tungsten (W), molybdenum (Mo), cobalt (Co), and ruthenium (Ru).

In some embodiments, the reactive inhibition gas is nitrogen-containing. In some embodiments, the reactive inhibition gas is ammonia (NH3) or hydrazine (N2H4).

In some embodiments, the method further comprises determining an offset from delay parameters. In some such embodiments, the determining the offset comprises optimizing within-wafer uniformity.

In some embodiments, the method further includes deposition of a metal before and/or after the inhibition treatment. A deposition operation may be performed in the same or different chamber as the inhibition treatment. In some embodiments, it is performed in a first station of a multi-station chamber, with the inhibition treatment performed in a second station. In some embodiments, a deposition is performed by atomic layer deposition (ALD) using the metal precursor and a reducing gas. It may or may not include a co-flow pulse.

Another aspect of the disclosure relates to an apparatus including: a chamber comprising one or more stations, each station comprising a pedestal and a showerhead disposed over the pedestal and configured to be fluidically connected to a first gas source and a second gas source; and a controller comprising instructions for: introducing multiple co-flow pulses of the first gas and the second gas into a station of the chamber, wherein each co-flow pulse comprises a pulse of the first gas and a pulse of the second gas, wherein the pulse of the first gas and the pulse of the second gas are offset and overlap in time, and wherein the each pulse of the first gas is separated from subsequent pulses of the first gas by a purge and each pulse of the second gas is separated from subsequent pulses of the second gas by a purge. The pulses (also referred to as doses) are measured from when the gas is flowed from its gas source.

In some embodiments, the controller further comprises instructions for determining an offset from one or more parameters. In some such embodiments, the controller further comprises instructions for receiving the one or more parameters.

In some such embodiments, the one or more parameters comprise a subset or all of: the identity of a gas to be delayed, the length of offset, and whether to shorten a pulse or shorten a purge.

In some embodiments, the controller further comprises instructions for modifying a pulse sequence of the first gas or the second gas in accordance with the determined offset.

Another aspect of the disclosure relates to a method comprising: introducing multiple co-flow pulses of a first gas and a second gas into a processing chamber, wherein each co-flow pulse comprises a pulse of the first gas and a pulse of the second gas, wherein the pulse of the first gas and the pulse of the second gas are offset and overlap in time, and wherein the each pulse of the first gas is separated from subsequent pulses of the first gas by a purge and each pulse of the second gas is separated from subsequent pulses of the second gas by a purge. The pulses (also referred to as doses) are measured from when the gas is flowed from its gas source.

In some embodiments, the method further involves determining an offset from one or more parameters. In some such embodiments, the method involves receiving the one or more parameters. In some embodiments, the one or more parameters comprise a subset of all of: the identity of a gas to be delayed, the length of offset, and the whether to shorten a pulse or purge.

In some such embodiments, the method further comprises modifying a pulse sequence of the first gas or the second gas in accordance with the determined offset.

Another aspect of the disclosure relates to a tangible machine-readable medium including instructions for: introducing multiple co-flow pulses of a first gas and a second gas into a processing chamber, wherein each co-flow pulse comprises a pulse of the first gas and a pulse of the second gas, wherein the pulse of the first gas and the pulse of the second gas are offset and overlap in time, and wherein the each pulse of the first gas is separated from subsequent pulses of the first gas by a purge and each pulse of the second gas is separated from subsequent pulses of the second gas by a purge. The pulses (also referred to as doses) are measured from when the gas is flowed from its gas source.

In some embodiments, the tangible machine-readable medium further includes instructions for determining an offset from one or more parameters.

In some embodiments, the tangible machine-readable medium further includes instructions for receiving the one or more parameters from a user input. In some embodiments, the one or more parameters include a subset or all of: the identity of a gas to be delayed, the length of offset, and the whether to shorten a pulse or purge. In some embodiments, the tangible machine-readable medium further includes modifying a pulse sequence of the first gas or the second gas in accordance with the determined offset.

These and other aspects of the disclosure are described further below with reference to the Drawings.

### BRIEF DESCRIPTION OF DRAWINGS

FIG. 1 shows an example of a deposition-inhibition-deposition (DID) process for feature fill that may be implemented according to various embodiments described herein.

FIG. 2 shows example timing sequences for co-flow pulses without and with a phase shift.

FIG. 3 shows example timing sequences for two cycles of co-flow pulses of A and B process gases with B delay.

FIG. 4 shows on wafer flows of A and B gases that correspond to the timing sequences shown in FIG. 2.

FIG. 5 shows examples of transient simulation results of NH₃ mass fraction and WF₆ vs position from the center of the wafer as generated by simulation.

FIG. 6 shows plots of nucleation delay at the center and edge of a wafer as a function of reactant delay for various NH₃/WF₆ inhibition processes.

FIG. 7 shows an example of a timing sequence diagram showing example cycles of a method for depositing a tungsten nucleation layer using diborane.

FIG. 8 shows an example of the timing sequence diagram in FIG. 7 modified to include a delay.

FIG. 9a shows an example of a dual plenum showerhead configured to deliver two gases separately to a chamber.

FIG. 9b shows an example of charge vessels connected to a showerhead.

FIG. 10 shows a schematic illustration of gas flow, including a mass flow controller (MFC), a charge vessels (CV), and outlet valve connected to a showerhead.

FIG. 11 shows an apparatus that may be used in accordance with certain embodiments.

FIG. 12 shows an example of a multi-station apparatus that may be used with certain embodiments.

### DESCRIPTION

Examples of various embodiments are illustrated in the accompanying drawings and described further below. It will be understood that the discussion herein is not intended to limit the claims to the specific embodiments described. On the contrary, it is intended to cover alternatives, modifications, and equivalents as may be included within the spirit and scope of the disclosure and the appended claims. In the following description, numerous specific details are set forth in order to provide a thorough understanding the disclosed subject matter. Various implementations of subject may be practiced without some or all these specific details. In other instances, well-known process operations have not been described in detail in order not to unnecessarily obscure the subject matter described herein.

Provided herein are methods and apparatuses for reactant delivery to semiconductor substrates. The methods and apparatuses may be used in processes that include pulsed co-flow of gases. Pulsed co-flow of gases refers to gases delivered to a chamber housing a substrate in pulses such that the gases exist in the chamber at the same time. They are delivered separately to the chamber and are not pre-mixed. One example of a process that may include pulsed co-flow of reactants is an inhibition operation in a deposition-inhibition-deposition (DID) sequence. The co-flowed gases may be described herein as reactants although it should be noted that they may not necessarily react during the process.

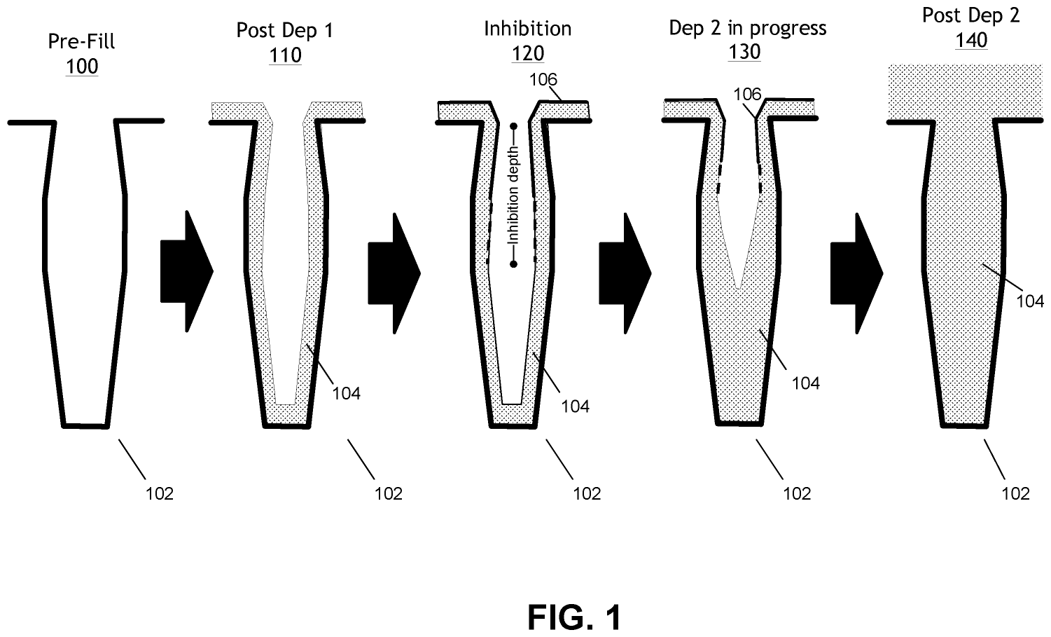

FIG. 1 shows an example of a DID process that may be implemented according to various embodiments described herein. First, at 100, an unfilled feature 102 is shown at a pre-fill stage. The feature 102 may be formed in one or more layers on a semiconductor substrate and may optionally have one or more layers that line the sidewalls and/or bottom of the feature. At 110, the feature 102 is shown after an initial deposition of the fill material to form a layer of the material 104 to be filled in the feature 102. Examples of material include tungsten, cobalt, molybdenum, and ruthenium though the techniques described herein may be used to for inhibition of any appropriate material.

At 120, the feature 102 is shown after an inhibition treatment. The inhibition treatment is a treatment that has the effect of inhibiting subsequent deposition on the treated surfaces 106. The inhibition may involve various mechanisms depending on various factors including the surfaces to be treated and the inhibition chemistry. In the methods described herein, the inhibition is a thermal (i.e., non-plasma) process. In one example, tungsten nucleation, and thus tungsten deposition, is inhibited by exposure to a nitrogen-containing chemistry. This can involve exposure to ammonia vapor in an example of a thermal process.

Examples of inhibition mechanisms can include a chemical reaction between inhibition species and the feature surface to form a thin layer of a compound material such as tungsten nitride (WN) or tungsten carbide (WC). In some embodiments, inhibition can involve a surface effect such as adsorption that passivates the surface without forming a layer of a compound material. It should be noted that the methods described herein do not rely on a detailed or complete understanding of the physical mechanisms that cause the inhibition behavior.

The inhibition may be characterized by an inhibition depth and an inhibition gradient. That is, the inhibition may vary with depth, such that the inhibition is greater at the feature opening than at the bottom of the feature and may extend only partway into the feature. In the depicted example, the inhibition depth is about half of the full feature depth. In addition, the inhibition treatment is stronger at the top of the feature, as graphically shown by the dotted line deeper within the feature.

Because deposition is inhibited near the feature opening, during the Dep2 stage shown at 130, the material preferentially deposits at the feature bottom while not depositing or depositing to a less extent at the feature opening. This can prevent the formation of voids and seams within the filled feature. As such, during Dep2, the material 104 may be filled in a manner characterized as bottom-up fill rather than the conformal Dep1 fill. As the deposition continues, the inhibition effect may be removed, such that deposition on the lightly treated surfaces may no longer be inhibited. This is illustrated at 130, with the treated surfaces 106 being less extensive than prior to the Dep2 stage. In the example of FIG. 1, as the Dep2 proceeds, the inhibition is eventually overcome on all surfaces and the feature is completely filled with the material 104 as shown at 140.

While DID process in FIG. 1 shows the feature preferentially inhibited at the top of the feature, in some embodiments, the entire feature may be inhibited. Such a process can be useful for preventing line bending, for example.

The inhibition operation can include pulsed co-flow of an inhibition gas and a precursor gas. For example, in a DID process for tungsten fill, the inhibition operation 120 can involve a pulses of process gases including a reactive inhibition gas such as ammonia (NH₃) and a tungsten precursor such as (WF₆). Pulses of the inhibition gas are separated by an inert purge gas such as argon (Ar). Pulses of the precursor are also separated by an inert purge gas. When the process gases are co-flowed, they are introduced separately to the chamber and are in vapor phase at the same time in the chamber.

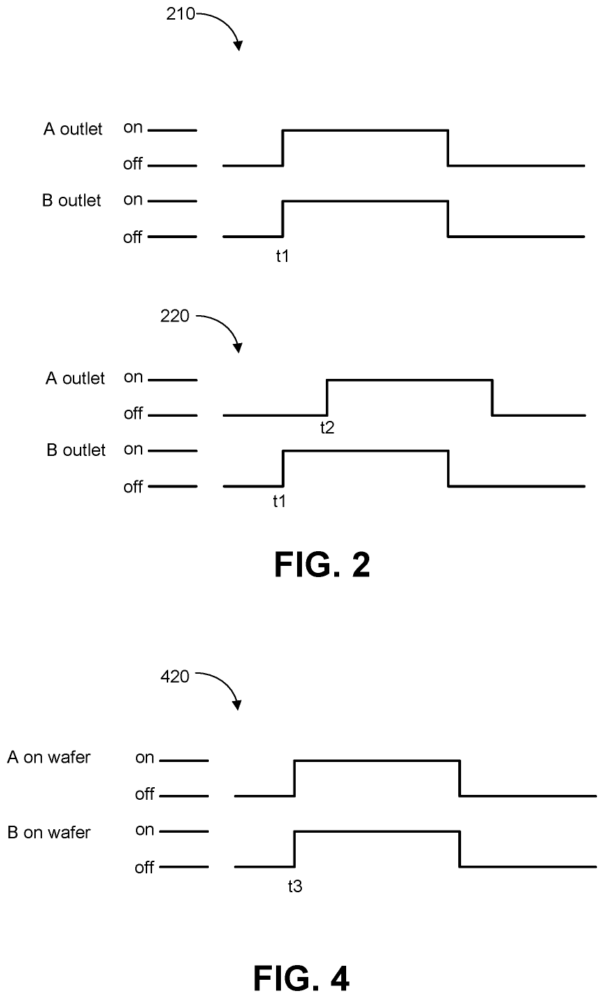

In the methods provided herein, co-flow of gases may be phase shifted for improved uniformity and/or performance. FIG. 2 shows examples timing sequences for co-flow pulses without and with a phase shift. A phase shift may also be referred to as a delay. A pulse is also referred to as a dose.

In FIG. 2, “A outlet” and “B outlet” refer to the flows of A and B, respectively, at gas source outlets. At sequence 210, there is no delay with flow of both gases turned on at a time t1. At sequence 220, gases A is delayed, such that flow of gas A from its gas source outlet is turned on at time t2.

In some embodiments, the methods are implemented by specifying one or more parameters. For example, a user may input the following parameters to specify a delay.

| Parameter | Description | Value |
|---|---|---|
| Delay | Specify co-flow delay | Time of delay |
| | between A and B | (e.g., 0.5 s) |
| DelayType | Shorten dose or purge | 0 = shorten dose |
| | | 1 = shorten purge |
| DelayGas | Specify which gas to delay | 0 = delay B |
| | | 1 = delay A |

In the above table, the following parameters are shown. Delay refers to the time value of a delay between flowing gas A and B from the gas source outlet. In an example, the delay is 0.5 seconds. In some embodiments, there are two types of delay: one in which a dose is shortened and one in which purge between sequential doses is shortened. In the above table, the DelayType parameter is 0 to shorten the dose and 1 to shorten the purge. The DelayGas parameter indicates which gas to delay, e.g., 0 for a B delay and 1 for an A delay.

It should be noted that the dose onset is when the valve that allows flow to the showerhead is opened. This is referred to as the “gas source,” which can be a charge vessel, a distribution line, or any other container or line in which the gas is contained. In some embodiments, the charge vessel and/or distribution line is housed in a gas box.

A co-flow sequence with no delay and equal purge times after A and B and equal dose times for gases A and B can be used as reference. By shortening the dose or purge, the A and B cycles can end at the same time in some embodiments. In other embodiments, both a purge after and dose of a gas may be shortened with respect to the other. And in some embodiments, the dose and purge times may be the same, with the entire A and B cycles offset. In many embodiments, however, the doses overlap.

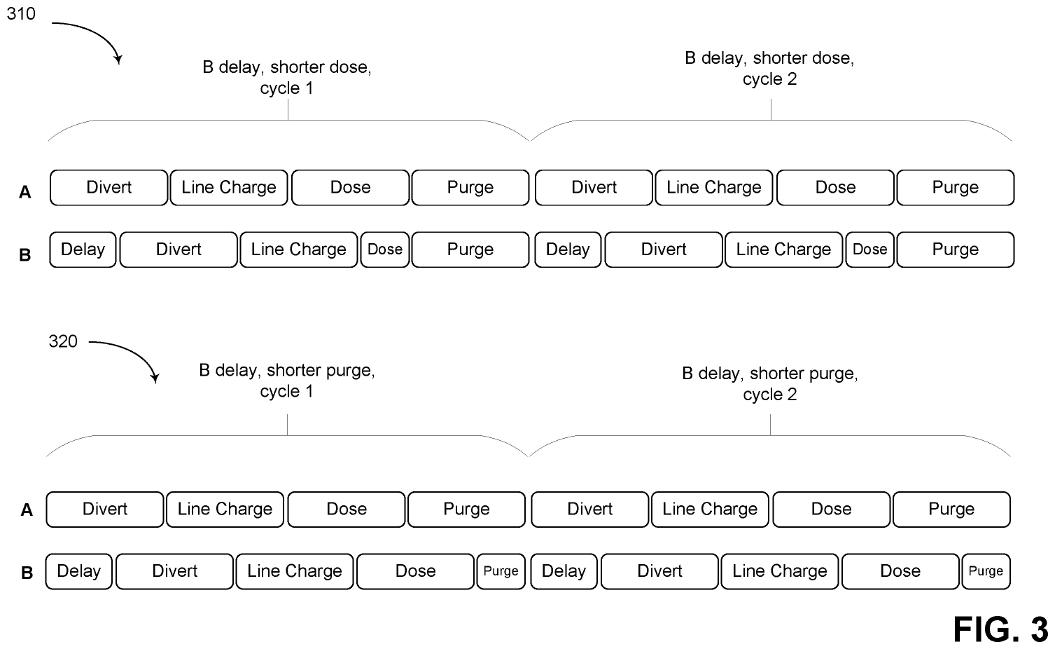

FIG. 3 shows timing sequences for two examples of two cycles of co-flow pulses of A and B process gases with B delay. The timing sequences of each of gas “A” and gas “B” show divert, line charge, dose, and purge. The deposition station which the gases are flowed may include a divert line directly to the process vacuum exhaust such that process gasses can bypass the deposition station. A gas manifold system may be used to provide line charges to the various gas distribution lines. A line charge refers to pressurizing the distribution line. As described further below, in certain embodiments, a charge vessel may be used. After a suitable increment of time, an outlet valve of the charge vessel is opened and gas delivered to the chamber. After a suitable time for delivery of the gas (the dose time), the valve is closed. The chamber can then be purged. The dose and/or purge delays are not dependent on a particular mode of delivery to the chamber including the presence of absence of a divert and/or line charge.

In the example of FIG. 3, at 310, B is delayed with a shorter dose time than the A dose. The A purge and the B purge remain the same. At 320, B is delayed with a shorter purge time. The A dose and B dose remain the same.

During the B delay shown at 310 and 320, there may be argon or other purge gas flowing or nothing flowing through the B inlet to the deposition station. A dose starts from the time the valve allowing it to flow to the station is opened and ends when it is closed (or flow is otherwise stopped). A dose of may also be referred to as a pulse of the gas.

In some embodiments, the delay compensates for different delivery times to the substrate. Such a difference may be due to difference in flow rates, or the location or volume of gas boxes, delivery lines, or showerhead plenums, for example. As such, a pulse delay of A at a gas box or other source outlet as in FIG. 2 can result in “true co-flow” at the wafer. In one example, the delay shown in FIG. 2 at 220 results in a true co-flow at the wafer as shown at 420 in FIG. 4.

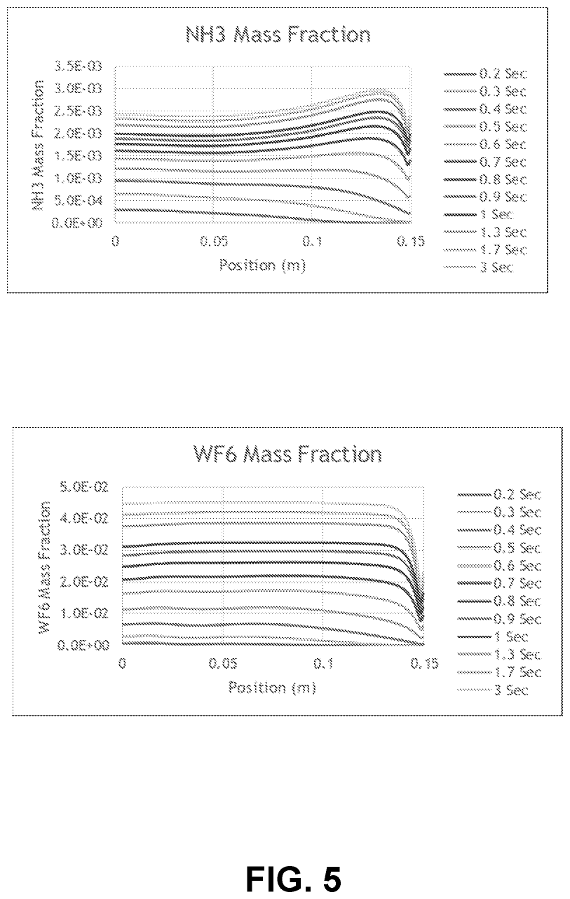

FIG. 5 shows examples of transient simulation results of NH₃ mass fraction and WF₆ vs position from the center of the wafer as generated by simulation. In each of the plots, the lines represent 0.2 s, 0.3 s, 0.4 s, 0.5 s, 0.6 s, 0.7 s, 0.8 s, 0.9 s, 1 s, 1.3 s., 1.7 s, and 3 s. The results indicate that NH₃ reaches the wafer before WF₆. Thus, a delay of NH₃ with respect to WF₆ allows the gases to reach the wafer at the same time for in the examples of FIG. 5.

Typically the delay to allow co-flow at the wafer is shorter than the dose time itself such that the doses overlap in time. However, there may instances in which the doses do not overlap, for example, if the difference in time to reach the wafer is longer than the dose time.

In alternate embodiments, the delay in dose may result in a delay at the wafer surface, which may be advantageous in certain processing.

While experimental or simulation results can be used to help determine which gas is delayed and for how long, in some embodiments, the methods described herein do not rely on a detailed or complete understanding of the gas flows at the wafer surface.

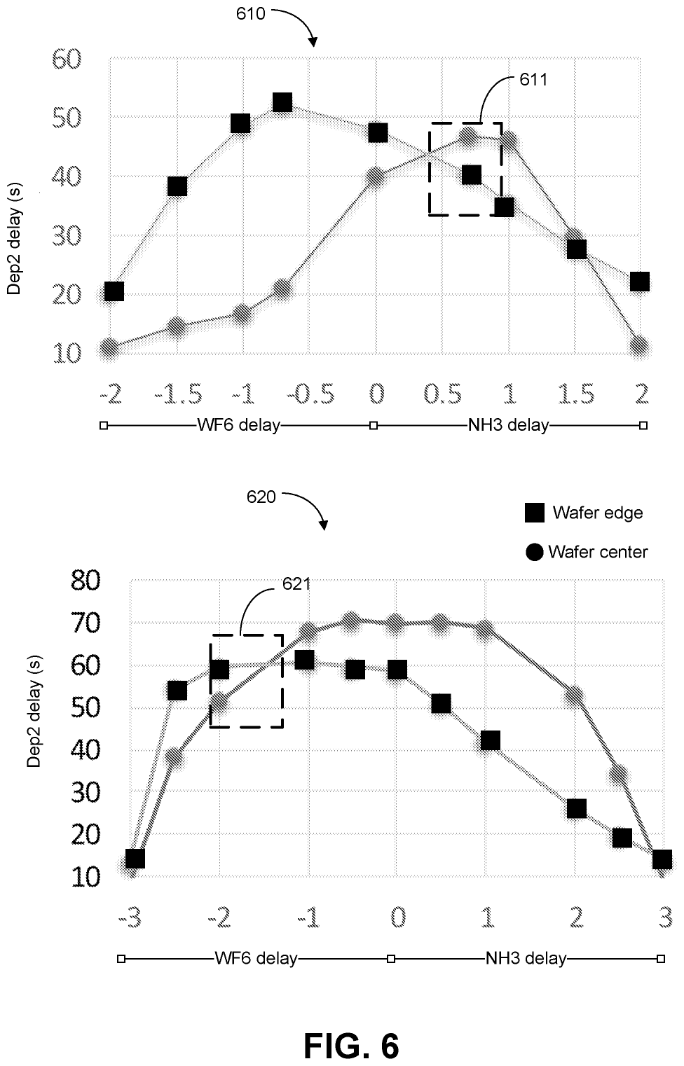

In some embodiments, a delay may be determined by optimizing results such as uniformity and/or a performance characteristic. FIG. 6 shows examples of determining delays to improve within-wafer uniformity for two inhibition processes. Nucleation delays at the edge and center of wafer were measured a NH₃/WF₆ co-flow inhibition process with low WF₆ for various gas flow delays and plotted in plot 610. The left side of the plot shows results for WF₆ delay and the right side for NH₃ delay.

The center and edge delays are represented by separate curves and are closest at the positions indicated by the box 611, with a NH₃ delay of between about 0.5 seconds (s) and 1 s. This indicates the best center to edge uniformity. Within wafer non-uniformity (WiW NU) was measured for no delay and an optimized delay. The delay resulted in a decrease from 7% to 3.5% WiW NU.

A similar plot 620 was generated for an NH₃/WF₆ co-flow inhibition process with high WF₆ flow. Here, the best uniformity is obtained at a WF₆ delay of between about 1 s and 2 s. WiW NU) was measured for no delay and an optimized delay. The delay resulted in a decrease from 8% to 5% WiW NU.

In addition to or instead of uniformity, delay can be used to tune a particular performance characteristic. For example, a delay of between about 0.5 s and 1 s may be used in the low WF₆ process to maximize edge inhibition.

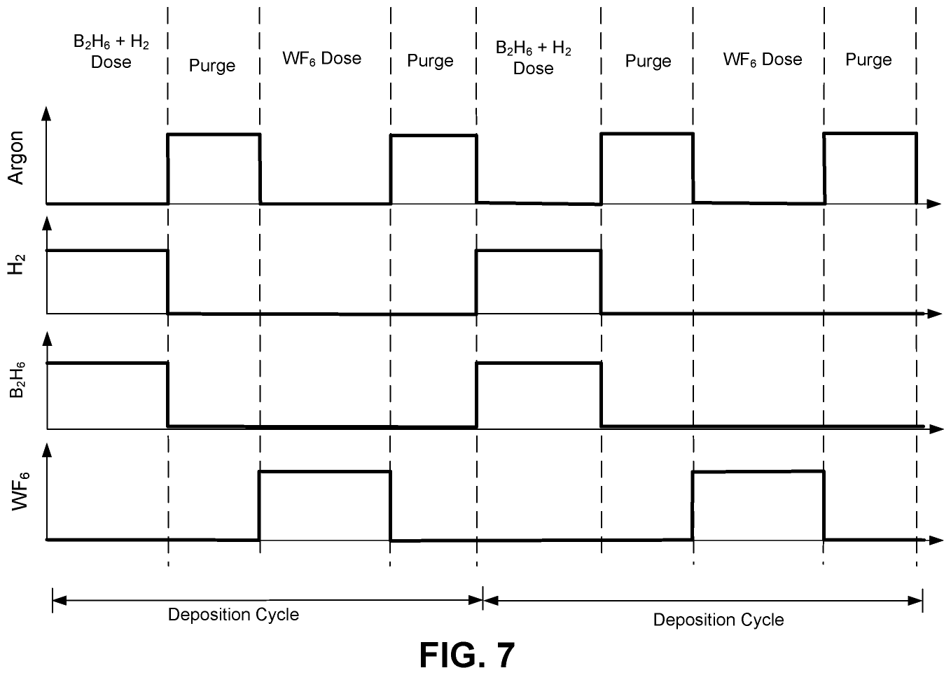

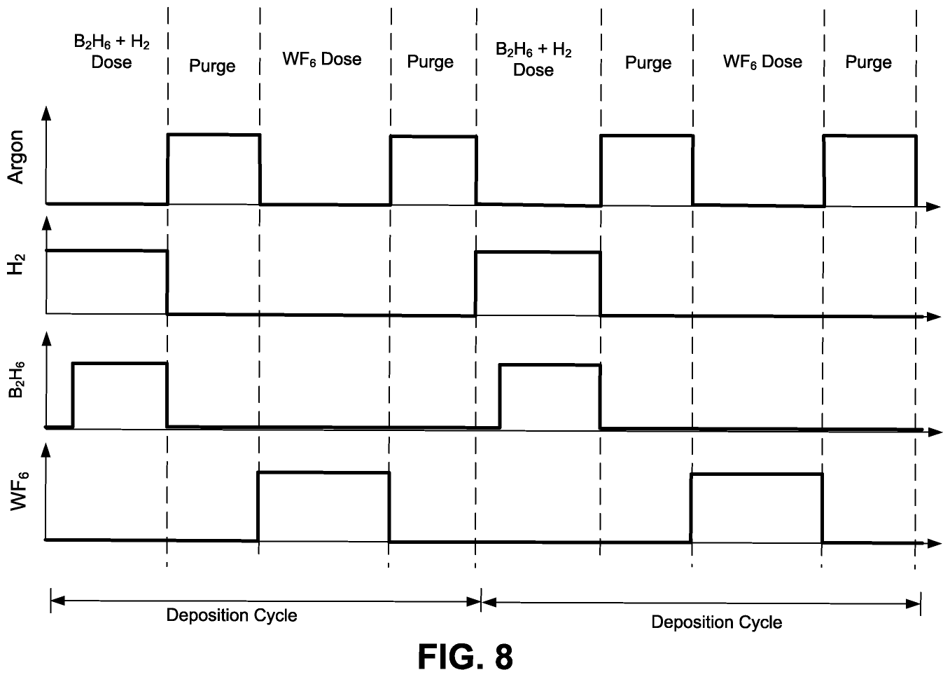

In addition to inhibition processes, the methods and apparatus described herein may be implemented with other pulsed co-flow processes. One example includes atomic layer deposition (ALD) processes in which one of the reactants is co-flowed with another gas. For example, FIG. 7 shows an example of a timing sequence diagram showing example cycles of a method for depositing a tungsten nucleation layer using diborane. As shown in FIG. 7, hydrogen is flowed only during the diborane pulse. By co-flowing H₂ with the boron-containing reducing agent but not with the tungsten-containing precursor flow, step coverage and conformality of the nucleation layer can be improved. In FIG. 8, a timing sequence of a B₂H₆ delay with shortened dose is shown.

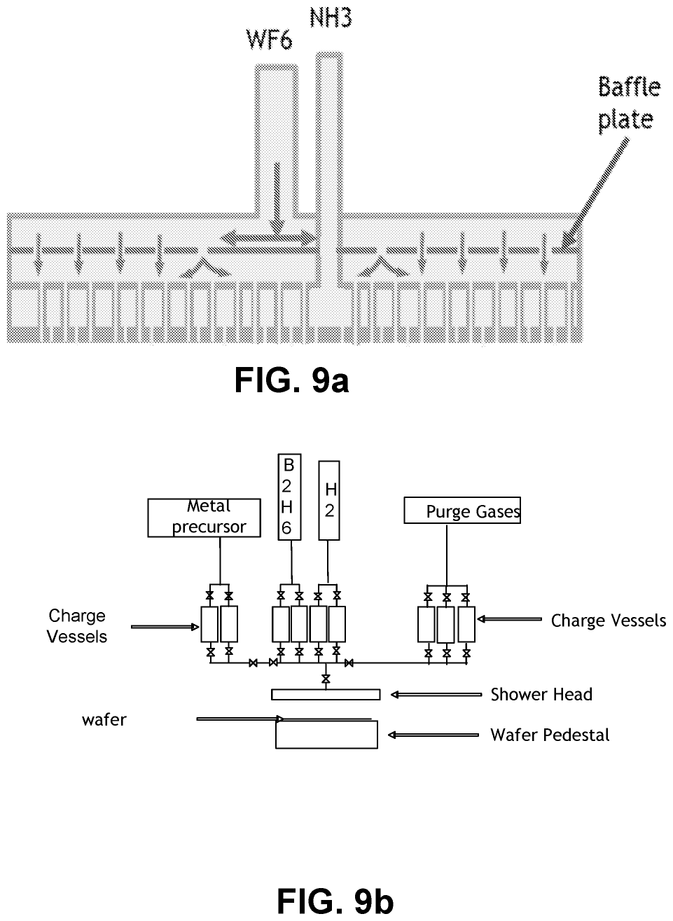

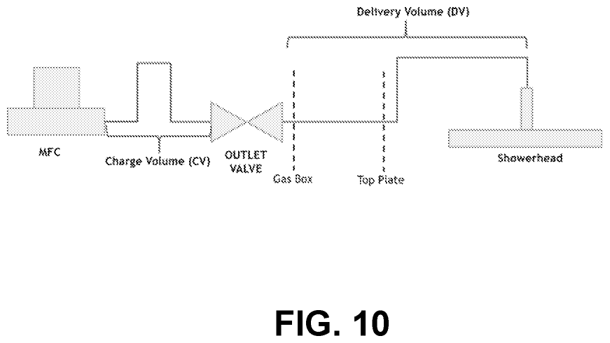

The processes described herein may be used with any chamber and gas delivery system configured to individually deliver two or more gases to a chamber. FIG. 9a shows an example of a dual plenum showerhead configured to deliver two gases separately to a chamber. In the example of FIG. 9a, WF₆ and NH₃ are delivered. WF₆ is delivered through the upper plenum and NH₃ through the lower plenum, with the gases separated until exiting the showerhead. Single plenum showerheads may also be used, with the gases potentially mixing in the showerhead. Regardless of the showerhead, different gas sources are connected to it, e.g., as shown in FIG. 9b, which illustrates a configuration for deposition a metal nucleation layer using a B₂H₆/H₂ co-flow as described above. FIG. 10 shows a schematic illustration of gas flow, including a mass flow controller (MFC), a charge vessels (CV), and outlet valve connected to a showerhead. As described above, a dose begins when the outlet valve(s) is opened to allow flow from the gas source (gas box in the Example of FIG. 10) to the showerhead.

In other embodiments, one of the two reactant flows may be in a continuous flow mode during the inhibition or other process, with the other reactant flow pulsed with or without delay. This can also permit co-flow at the wafer.

### Metal-Containing Precursors

In particular embodiments, the methods may be used as part of inhibition-deposition processes, including DID processes, of cobalt, molybdenum, or ruthenium films or compound films containing these metals. While WF₆ is used as an example of a tungsten-containing precursor in the above description, it should be understood that other tungsten-containing precursors may be suitable for performing disclosed embodiments. For example, a metal-organic tungsten-containing precursor may be used. Organo-metallic precursors and precursors that are free of fluorine, such as MDNOW (methylcyclopentadienyl-dicarbonylnitrosyl-tungsten) and EDNOW (ethylcyclopentadienyl-dicarbonylnitrosyl-tungsten) may also be used. Chlorine-containing tungsten precursors (WClₓ) such as tungsten pentachloride (WCl₅) and tungsten hexachloride (WCl₆) may be used.

To deposit molybdenum (Mo), Mo-containing precursors including molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆) may be used.

To deposit ruthenium (Ru), Ru-precursors may be used. Examples of ruthenium precursors that may be used for oxidative reactions include (ethylbenzyl)(1-ethyl-1,4-cyclohexadienyl)Ru(0), (isopropyl-4-methylbenzyl)(1,3-cyclohexadienyl)Ru(0), 2,3-dimethyl-1,3-butadienyl)Ru(0)tricarbonyl, (1,3-cyclohexadienyl)Ru(0)tricarbonyl, and (cyclopentadienyl)(ethyl)Ru(II)dicarbonyl. Examples of ruthenium precursors that react with non-oxidizing reactants are bis(5-methyl-2,4-hexanediketonato)Ru(II)dicarbonyl and bis(ethylcyclopentadienyl)Ru(II).

To deposit cobalt (Co), cobalt-containing precursors including dicarbonyl cyclopentadienyl cobalt (I), cobalt carbonyl, various cobalt amidinate precursors, cobalt diazadienyl complexes, cobalt amidinate/guanidinate precursors, and combinations thereof may be used.

The metal-containing precursor may be reacted with a reducing agent as described above. In some embodiments, H₂ is used as a reducing agent for bulk layer deposition to deposit high purity films.

### Nucleation Layer Deposition

In some implementations, the methods described herein involve deposition of a nucleation layer prior to deposition of a bulk layer. A nucleation layer is typically a thin conformal layer that facilitates subsequent deposition of bulk material thereon. For example, a nucleation layer may be deposited prior to any fill of the feature and/or at subsequent points during fill of the feature (e.g., via interconnect) on a wafer surface. For example, in some implementations, a nucleation layer may be deposited following etch of tungsten in a feature, as well as prior to initial tungsten deposition.

In certain embodiments, a first deposition in a DID process is a nucleation layer. The first deposition may also be a bulk layer or a nucleation+bulk layer.

In certain implementations, the nucleation layer is deposited using a pulsed nucleation layer (PNL) technique. In a PNL technique to deposit a tungsten nucleation layer, pulses of a reducing agent, optional purge gases, and tungsten-containing precursor are sequentially injected into and purged from the reaction chamber. The process is repeated in a cyclical fashion until the desired thickness is achieved. PNL broadly embodies any cyclical process of sequentially adding reactants for reaction on a semiconductor substrate, including atomic layer deposition (ALD) techniques. Nucleation layer thickness can depend on the nucleation layer deposition method as well as the desired quality of bulk deposition. In general, nucleation layer thickness is sufficient to support high quality, uniform bulk deposition. Examples may range from 10 Å-100 Å.

The methods described herein are not limited to a particular method of nucleation layer deposition but include deposition of bulk film on nucleation layers formed by any method including PNL, ALD, CVD, and physical vapor deposition (PVD). Moreover, in certain implementations, bulk tungsten may be deposited directly in a feature without use of a nucleation layer. For example, in some implementations, the feature surface and/or an already-deposited under-layer supports bulk deposition. In some implementations, a bulk deposition process that does not use a nucleation layer may be performed.

In various implementations, tungsten nucleation layer deposition can involve exposure to a tungsten-containing precursor such as tungsten hexafluoride (WF₆), tungsten hexachloride (WCl₆), and tungsten hexacarbonyl (W(CO)₆). In certain implementations, the tungsten-containing precursor is a halogen-containing compound, such as WF₆. Organo-metallic precursors, and precursors that are free of fluorine such as MDNOW (methylcyclopentadienyl-dicarbonylnitrosyl-tungsten) and EDNOW (ethylcyclopentadienyl-dicarbonylnitrosyl-tungsten) may also be used.

Examples of reducing agents can include boron-containing reducing agents including diborane (B₂H₆) and other boranes, silicon-containing reducing agents including silane (SiH₄) and other silanes, hydrazines, and germanes. In some implementations, pulses of metal-containing can be alternated with pulses of one or more reducing agents, e.g., S/W/S/W/B/W, etc., W represents a tungsten-containing precursor, S represents a silicon-containing precursor, and B represents a boron-containing precursor. In some implementations, a separate reducing agent may not be used, e.g., a tungsten-containing precursor may undergo thermal or plasma-assisted decomposition.

Metal precursors for other metals are described above.

### Bulk Deposition

As described above, bulk deposition may be performed across a wafer. In some implementations, bulk deposition can occur by a CVD process in which a reducing agent and a metal-containing precursor are flowed into a deposition chamber to deposit a bulk fill layer in the feature. An inert carrier gas may be used to deliver one or more of the reactant streams, which may or may not be pre-mixed. Unlike PNL or ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted. Bulk deposition may also be performed using ALD processes in which a metal-containing precursor is alternated with a reducing agent such as H₂.

It should be understood that the metal films described herein may include some amount of other compounds, dopants and/or impurities such as nitrogen, carbon, oxygen, boron, phosphorous, sulfur, silicon, germanium and the like, depending on the particular precursors and processes used. The metal content in the film may range from 20% to 100% (atomic) metal. In many implementations, the films are metal-rich, having at least 50% (atomic) metal, or even at least about 60%, 75%, 90%, or 99% (atomic) metal. In some implementations, the films may be a mixture of metallic or elemental metal (e.g., W, Mo, Co, or Ru) and other metal-containing compounds such as tungsten carbide (WC), tungsten nitride (WN), molybdenum nitride (MoN) etc. CVD and ALD deposition of these materials can include using any appropriate precursors as described above.

In some embodiments, the first and second depositions in a DID process involve bulk deposition using an ALD process that uses H₂ as reducing agent. Metal precursors are described above.

### Inhibition of Metal Nucleation

Thermal inhibition processes generally involve exposing the feature to a nitrogen-containing compound such as ammonia (NH₃) or hydrazine (N₂H₄) to non-conformally inhibit the feature near the feature opening. In some embodiments, the thermal inhibition processes are performed at temperatures ranging from 250° C. to 450° C. At these temperatures, exposure of a previously formed tungsten or other layer to NH₃ results in an inhibition effect. Other potentially inhibiting chemistries such as nitrogen (N₂) or hydrogen (H₂) may be used for thermal inhibition at higher temperatures (e.g., 900° C.). For many applications, however, these high temperatures exceed the thermal budget. In addition to ammonia, other hydrogen-containing nitriding agents such as hydrazine may be used at lower temperatures appropriate for back end of line (BEOL) applications.

Nitridation of a surface can passivate it. Subsequent deposition of tungsten or other metal such as molybdenum or cobalt on a nitrided surface is significantly delayed, compared to on a regular bulk tungsten film. In addition to NF₃, fluorocarbons such as CF₄ or C₂F₈ may be used. However, in certain implementations, the inhibition species are fluorine-free to prevent etching during inhibition.

In addition to the surfaces described above, nucleation may be inhibited on liner/barrier layers surfaces such as TiN and/or WN surfaces. Any chemistry that passivates these surfaces may be used. Inhibition chemistry can also be used to tune an inhibition profile, with different ratios of active inhibiting species used. For example, for inhibition of W surfaces, nitrogen may have a stronger inhibiting effect than hydrogen; adjusting the ratio of N₂ and H₂ gas in a forming gas can be used to tune a profile.

In certain implementations, the substrate can be heated up or cooled down before inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the gas source.

In some embodiments, inhibition can involve a chemical reaction between the thermal inhibitor species and the feature surface to form a thin layer of compound material such a metal nitride film. In some embodiments, inhibition can involve a surface effect such as adsorption that passivates the surface without forming a layer of a compound material.

Embodiments of the methods described herein are not limited to a particular inhibition chemistry. The inhibition gas may be referred to as a reactive inhibition gas regardless of the mechanism of inhibition. It is distinguished from inert gases such as helium (He) and argon (Ar) and other non-reactive gases that may be used to direct gas flow without reacting or causing a surface effect.

As described above, in the methods described herein, a metal precursor gas may also be flowed during the inhibition. According to various embodiments, a small amount of film may be deposited during the inhibition due to the presence of the precursor.

### Apparatus

The methods presented herein may be carried out in various types of deposition apparatuses available from various vendors. Examples of a suitable apparatus include a Concept-1 ALTUS™, a Concept 2 ALTUS™, a Concept-2 ALTUS-S™, Concept 3 ALTUS™ deposition system, ALTUS Max™, ALTUS® Max ICEFill™ or any of a variety of other commercially available deposition tools. Stations in both single station and multi-station deposition apparatuses can be used to perform the methods described above.

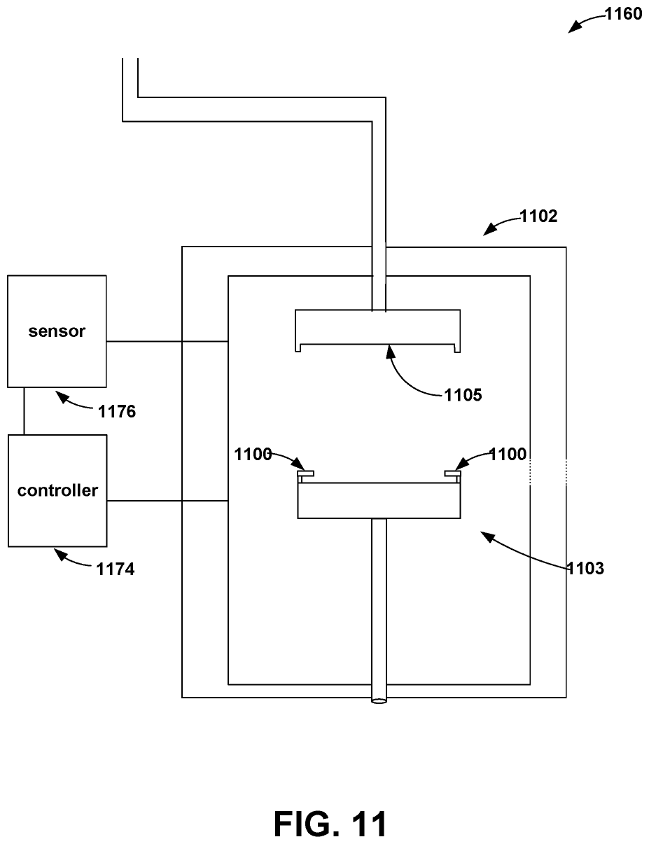

FIG. 11 shows an apparatus 1160 that may be used in accordance with various methods previously described. The deposition station 1102 has a substrate support 1103 that supports a wafer during deposition. An exclusion ring 1100 and showerhead 1105 are shown. As discussed above, the process gases may be fed through the showerhead 1105, with the substrate support equipped with a vacuum and, in some embodiments, a treatment gas source. In some embodiments, the showerhead 1105 is a dual plenum showerhead. If the substrate support is equipped with a treatment gas source, the inhibition treatment gas (e.g., NH₃) may be flowed through the substrate support to the back and/or edge of the wafer in addition through the showerhead. In such cases, the backside treatment gas may be pulsed with the frontside treatment gas, continuously flowed while the frontside treatment gas is pulsed, or as otherwise appropriate.

Gas sensors, pressure sensors, temperature sensors, etc. may be used to provide information on station conditions during various embodiments. Examples of station sensors that may be monitored during include mass flow controllers, pressure sensors such as manometers, thermocouples located in pedestal, and infra-red detectors to monitor the presence of a gas or gases in the station. In certain embodiments, a controller 1174 is employed to control process conditions of the station. Details on types of controllers are further discussed below with reference to FIG. 11 and the discussion with respect to this figure is applicable to the controller for the station as well as for the chamber. Sensors such as 1176 may be used to provide information to the controller 1174.

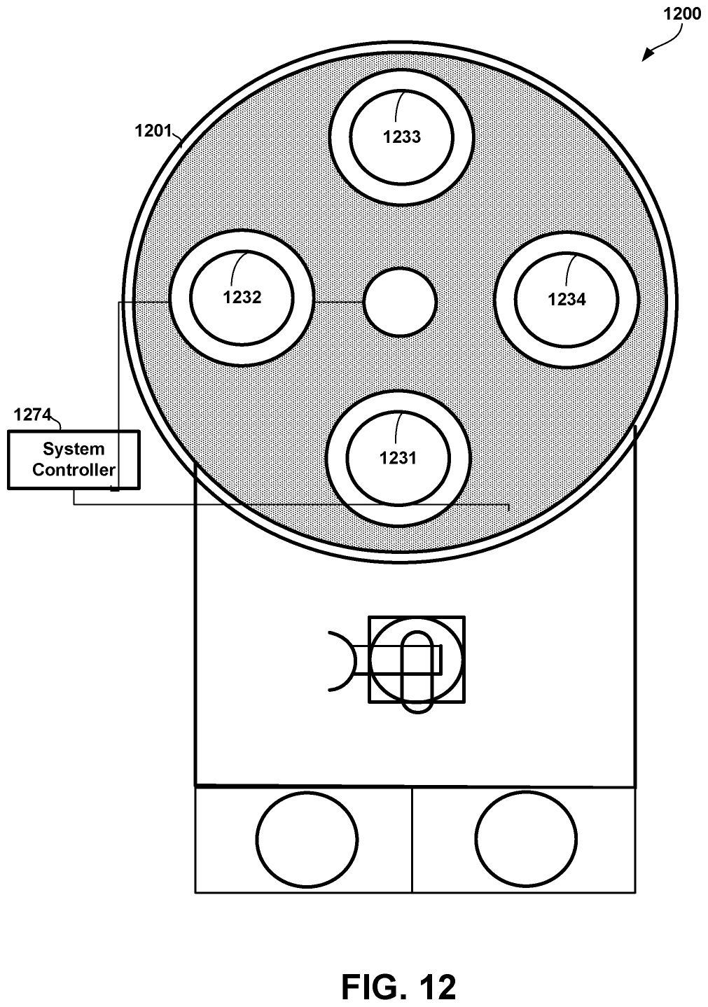

FIG. 12 shows an example of a multi-station apparatus that may be used with certain embodiments. The apparatus 1200 includes a processing chamber 1201, which houses multiple stations. The processing chamber can house at least two stations, or at least three stations, or at least four stations or more. FIG. 12 shows an apparatus 1200 with four stations 1231, 1232, 1233, and 1234. In some embodiments, all stations in the multi-station apparatus 900 with a processing chamber 1201 may be exposed to the same pressure environment controlled by the system controller 1274. Sensors (not shown) may also include a pressure sensor to provide chamber pressure readings. However, each station may have individual temperature conditions or other conditions.

In a deposition process, a wafer to be processed may be loaded through a load-lock into the station 1231. At this station, a nucleation and/or bulk layer deposition process may be performed. The wafer then may be indexed to station 1232 for an inhibition treatment including delay as described above. Bulk deposition may then be performed at stations 1233 and 1234. In other embodiments, the treatment may occur in the same station as one or both of the deposition operation in a DID sequence. Still further, any of these operations may be performed in a separate chamber.

In one example, a first deposition includes alternating doses of a metal precursor and a reducing agent at a first station, followed by a transfer of the substrate to a second station for an inhibition treatment with delay, followed by a transfer of the substrate to a third station for a second deposition including includes alternating doses of a metal precursor and a reducing agent at a first station. Example deposition sequences are given in FIGS. 7 and 8. In some embodiments, a H₂ reducing agent (with or without co-flow) may be used.

A system controller 1274 can control conditions of the indexing, the stations, and the processing chamber, such as the gas flows and pressure of the chamber. The system controller 1274 (which may include one or more physical or logical controllers) controls some or all the operations of a process chamber 1200. The system controller 1274 may include one or more memory devices and one or more processors. In some implementations, the system controller 1274 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller, which may control various components or subparts of the system or systems. The system controller depending on the processing parameters and/or the type of system, may be programmed to control any of the processes disclosed herein, including the delivery of processing gases, temperature settings (e.g., heating and/or cooling), pressure settings, vacuum settings, flow rate settings and times, fluid delivery settings, positional and operation settings, wafer transfers into and out of a tool and other transfer tools and/or load locks connected to or interfaced with a specific system.

Broadly speaking, the system controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the system controller receives instructions in the form of data, which specify parameters for each of the processing steps to be performed during one or more operations. The parameters may be specific to the type of process to be performed and the type of tool that the controller is configured to interface with or control. Thus, as described above, the system controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Patterning Method/Apparatus:

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically comprises some or all of the following steps, each step enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

1. A method comprising:
performing an inhibition treatment on the substrate in a chamber comprising flowing co-flow pulses of a reactive inhibition gas from a first gas source and a metal precursor gas from a second gas source to the chamber, wherein each co-flow pulse comprises a pulse of the reactive inhibition gas and a pulse of the metal precursor gas, wherein the pulse of the reactive inhibition gas and the pulse of the metal precursor gas, as measured from when each gas is flowed from its it gas source, are offset and overlap in time, and wherein the inhibition treatment inhibits metal nucleation.

2. The method of claim 1, wherein the pulse of the metal precursor gas and the pulse of the reactive inhibition gas end or start at the same time.

3. The method of claim 1, wherein each pulse of the reactive inhibition gas is separated from subsequent pulses of the reactive inhibition gas by a purge and each pulse of the metal precursor gas is separated from subsequent pulses of the metal precursor gas by a purge.

4. The method of claim 1, wherein the metal is one of tungsten (W), molybdenum (Mo), cobalt (Co), and ruthenium (Ru).

5. The method of claim 1, wherein the reactive inhibition gas is nitrogen-containing.

6. The method of claim 1, wherein the reactive inhibition gas is ammonia (NH₃) or hydrazine (N₂H₄).

7. The method of claim 1, further comprising determining an offset from delay parameters.

8. The method of claim 8, wherein the offset is determined by optimizing within-wafer uniformity.

9. The method of claim 1, further comprising, prior to the inhibition treatment, depositing a first metal layer on the substrate.

10. The method of claim 9, further comprising, after the inhibition treatment, depositing a second metal layer on the substrate.

11. The method of claim 10, wherein deposition of the first metal layer is in a first station of a multi-station chamber, the inhibition treatment is in a second station of a multi-station chamber, and deposition of the second metal layer is in a third layer of a multi-station chamber.

12. The method of claim 1, wherein the reactive inhibition gas and the metal precursor gas mix only after exiting the showerhead.

13. An apparatus comprising:
a chamber comprising one or more stations, each station comprising a pedestal and a showerhead disposed over the pedestal and configured to be fluidically connected to a first gas source and a second gas source; and
a controller comprising instructions for:
introducing multiple co-flow pulses of the first gas and the second gas into a station of the chamber, wherein each co-flow pulse comprises a pulse of the first gas and a pulse of the second gas, wherein the pulse of the first gas and the pulse of the second gas are offset and overlap in time, and wherein the each pulse of the first gas is separated from subsequent pulses of the first gas by a purge and each pulse of the second gas is separated from subsequent pulses of the second gas by a purge.

14. The apparatus of claim 13, wherein the controller further comprises instructions for determining an offset from one or more parameters.

15. The apparatus of claim 13, wherein the controller further comprises instructions for receiving the one or more parameters.

16. The apparatus of claim 15, wherein the one or more parameters comprise: the identity of a gas to be delayed, the length of offset, and the whether to shorten a pulse or purge.

17. The apparatus of claim 13, wherein the controller further comprises instructions for modifying a pulse sequence of the first gas or the second gas in accordance with the determined offset.

18. A method comprising:
introducing multiple co-flow pulses of a first gas and a second gas into a processing chamber, wherein each co-flow pulse comprises a pulse of the first gas from a first gas source and a pulse of the second gas from a second gas source, wherein the pulse of the first gas and the pulse of the second gas, as measured from when each gas is flowed from its it gas source, are offset and overlap in time, and wherein the each pulse of the first gas is separated from subsequent pulses of the first gas by a purge and each pulse of the second gas is separated from subsequent pulses of the second gas by a purge.

19. The method of claim 18, further comprising determining an offset from one or more parameters.

20. (canceled)

21. (canceled)

22. (canceled)

23. A tangible machine-readable medium comprising instructions for:
introducing multiple co-flow pulses of a first gas and a second gas into a processing chamber, wherein each co-flow pulse comprises a pulse of the first gas and a pulse of the second gas, wherein the pulse of the first gas and the pulse of the second gas are offset and overlap in time, and wherein the each pulse of the first gas is separated from subsequent pulses of the first gas by a purge and each pulse of the second gas is separated from subsequent pulses of the second gas by a purge.

24. (canceled)

25. (canceled)

26. (canceled)

27. (canceled)
